(19) United States
(12) Patent Application Publication
(10) Pub. No.: US 2025/0246917 A1
(43) Pub. Date: Jul. 31, 2025

(54) APPARATUS FOR CONTROLLING BATTERY AND METHOD THEREOF

(71) Applicants: HYUNDAI MOTOR COMPANY, Seoul (KR); Kia Corporation, Seoul (KR)

(72) Inventors: Yo Han BAEK, Hwaseong-si (KR); Ju Seok KIM, Hwaseong-si (KR); Ji Eun HWANG, Hwaseong-si (KR)

(73) Assignees: HYUNDAI MOTOR COMPANY, Seoul (KR); Kia Corporation, Seoul (KR)

(21) Appl. No.: 18/885,453

(22) Filed: Sep. 13, 2024

(30) Foreign Application Priority Data
Jan. 26, 2024 (KR) 10-2024-0012601

(51) Int. Cl. H02J 7/00; H01M 10/42; H01M 10/44; H01M 10/46

(52) U.S. Cl. CPC H02J 7/0014; H01M 10/425; H01M 10/441; H01M 10/46; H02J 7/007182; H01M 2010/4271

(57) ABSTRACT

In a battery control apparatus and a method thereof, the battery control apparatus may include a plurality of battery packs, and a processor. The processor may determine a target voltage based on obtaining voltage values respectively corresponding to the plurality of battery packs, may identify at least two adjustment battery packs for adjusting a voltage value among the plurality of battery packs based on comparing the target voltage and each of the voltage values, may perform a balancing charging and discharging sequence for adjusting voltage values of the at least two adjustment battery packs to the target voltage, based on performing a preprocessing sequence for battery balancing on the at least two adjustment battery packs, and may adjust the voltage values of the at least two adjustment battery packs within a first predetermined range including the target voltage based on the balancing charging and discharging sequence.

### CROSS-REFERENCE TO RELATED APPLICATION

The present application claims priority to Korean Patent Application No. 10-2024-0012601, filed on Jan. 26, 2024, the entire contents of which is incorporated herein for all purposes by this reference.

### BACKGROUND OF THE PRESENT DISCLOSURE

### Field of the Present Disclosure

The present disclosure relates to a battery control apparatus and a method thereof, and more particularly, relates to a battery pack balancing technology.

### Description of Related art

With the development of a technology for eco-friendly vehicles, research on batteries provided in the eco-friendly vehicles is underway. For example, the eco-friendly vehicles may include a hybrid electric vehicle (HEV), an electric vehicle (EV), a plug-in hybrid electric vehicle (PHEV), and/or a fuel cell electric vehicle (FCEV).

Accidents may be caused by voltage differences between battery packs included in the eco-friendly vehicles, and thus there is a need to perform battery pack balancing to reduce a voltage difference between battery packs.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing a battery control apparatus for controlling relays included in battery packs, and a method thereof.

Various aspects of the present disclosure are directed to providing a battery control apparatus for adjusting voltage values of battery packs to a target voltage by controlling the relays included in the battery packs, and a method thereof.

Various aspects of the present disclosure are directed to providing a battery control apparatus for shortening a balancing time by performing balancing on the battery packs, and a method thereof.

The technical problems to be solved by the present disclosure are not limited to the aforementioned problems, and any other technical problems not mentioned herein will be clearly understood from the following description by those skilled in the art to which the present disclosure pertains.

According to an aspect of the present disclosure, a battery control apparatus may include a plurality of battery packs, and a processor. The processor is configured to determine a target voltage based on obtaining voltage values respectively corresponding to the plurality of battery packs, may identify at least two adjustment battery packs for adjusting a voltage value among the plurality of battery packs based on comparing the target voltage and each of the voltage values, may perform a balancing charging and discharging sequence for adjusting voltage values of the at least two adjustment battery packs to the target voltage, based on performing a preprocessing sequence for battery balancing on the at least two adjustment battery packs, and may adjust the voltage values of the at least two adjustment battery packs within a first predetermined range including the target voltage based on the balancing charging and discharging sequence. Each of the battery packs may include at least two relays.

In an exemplary embodiment of the present disclosure, the processor may set states of a plurality of relays included in the plurality of battery packs as OFF states, may be configured to determine an average value based on storing the voltage values respectively corresponding to the plurality of battery packs, and may set the average value to the target voltage for identifying the at least two adjustment battery packs.

In an exemplary embodiment of the present disclosure, based on comparing the target voltage with each of the voltage values respectively corresponding to the plurality of battery packs, the processor may classify a battery pack with a voltage value within a second predetermined range including the target voltage among the plurality of battery packs as a first group, may classify a battery pack with a voltage value, which exceeds a first value from the target voltage, from among the plurality of battery packs as a second group, may classify a battery pack with a voltage value, which is smaller than a second value from the target voltage, from among the plurality of battery packs as a third group, and may identify a battery pack included in at least one of the second group, or the third group, or any combination thereof as the at least two adjustment battery packs.

In an exemplary embodiment of the present disclosure, the processor may obtain difference values between the target voltage and each of the voltage values based on comparing the target voltage with each of the voltage values respectively corresponding to the plurality of battery packs, may store the difference values based on sorting the difference values in a designated sorting method, and may perform the preprocessing sequence based on an order of the difference values.

In an exemplary embodiment of the present disclosure, the processor is configured to determine whether power of the at least two adjustment battery packs generated by a maximum current exceeds a rated power of a resistor, based on identifying the maximum current configured for being generated by the at least two adjustment battery packs, and may perform the preprocessing sequence based on the power of the at least two adjustment battery packs being smaller than or equal to the rated power.

In an exemplary embodiment of the present disclosure, the preprocessing sequence may set states of all relays as ON states by sequentially controlling the relays included in the at least two adjustment battery packs, and may set a state of at least part of the relays as an OFF state based on maintaining states of all the relays as the ON states during a predetermined time period.

In an exemplary embodiment of the present disclosure, the processor is configured to determine whether differences in voltage values between one battery pack included in the at least two adjustment battery packs and the other battery packs other than the one of the at least two adjustment battery packs exceed a first reference value, may be configured to determine whether at least one of the differences is maintained at the first reference value during a period exceeding a predetermined duration, based on at least one of the differences exceeding the first reference value, and may set states of relays included in the at least two adjustment battery packs as OFF states based on the at least one of the differences being maintained at the first reference value during the period exceeding the predetermined duration.

In an exemplary embodiment of the present disclosure, the processor is configured to determine whether at least one of the differences exceeds a second reference value smaller than the first reference value, based on at least one of the differences being smaller than or equal to the first reference value, and may maintain states of relays included in the at least two adjustment battery packs as current states based on at least one of the differences exceeding the second reference value.

In an exemplary embodiment of the present disclosure, the processor is configured to determine whether at least one of the differences exceeds a third reference value smaller than the second reference value, based on at least one of the differences being smaller than or equal to the second reference value. based on at least one of the differences exceeding the third reference value, the processor may maintain states of relays included in an adjustment battery pack with the greatest voltage value among the at least two adjustment battery packs as current states, may set a state of an anode relay among relays included in an adjustment battery pack with the smallest voltage value among the at least two adjustment battery packs as an ON state, and may set a state of a pre-charger (PC) relay among relays included in an adjustment battery pack with the smallest voltage value among the at least two adjustment battery packs as an OFF state.

In an exemplary embodiment of the present disclosure, based on at least one of the differences being smaller than or equal to the third reference value, the processor may set a state of an anode relay among relays included in the at least two adjustment battery packs to an ON state, and may set states of PC relays among the relays included in the at least two adjustment battery packs as OFF states.

According to an aspect of the present disclosure, a battery control method may include determining, by a processor, a target voltage based on obtaining voltage values respectively corresponding to a plurality of battery packs, identifying at least two adjustment battery packs for adjusting a voltage value among the plurality of battery packs based on comparing the target voltage and each of the voltage values, performing a balancing charging and discharging sequence for adjusting voltage values of the at least two adjustment battery packs to the target voltage, based on performing a preprocessing sequence for battery balancing on the at least two adjustment battery packs, and adjusting the voltage values of the at least two adjustment battery packs within a first predetermined range including the target voltage based on the balancing charging and discharging sequence. Each of the battery packs may include at least two relays.

The battery control method according to various exemplary embodiments of the present disclosure may include setting states of a plurality of relays included in the plurality of battery packs as OFF states, determining an average value based on storing the voltage values respectively corresponding to the plurality of battery packs, and setting the average value to the target voltage for identifying the at least two adjustment battery packs.

The battery control method according to various exemplary embodiments of the present disclosure may include, based on comparing the target voltage with each of the voltage values respectively corresponding to the plurality of battery packs, classifying a battery pack with a voltage value within a second predetermined range including the target voltage among the plurality of battery packs as a first group, classifying a battery pack with a voltage value, which exceeds a first value from the target voltage, from among the plurality of battery packs as a second group, classifying a battery pack with a voltage value, which is smaller than a second value from the target voltage, from among the plurality of battery packs as a third group, and identifying a battery pack included in at least one of the second group, or the third group, or any combination thereof as the at least two adjustment battery packs.

The battery control method according to various exemplary embodiments of the present disclosure may include obtaining difference values between the target voltage and each of the voltage values based on comparing the target voltage with each of the voltage values respectively corresponding to the plurality of battery packs, storing the difference values based on sorting the difference values in a designated sorting method, and performing the preprocessing sequence based on an order of the difference values.

The battery control method according to various exemplary embodiments of the present disclosure may include determining whether power of the at least two adjustment battery packs generated by a maximum current exceeds a rated power of a resistor, based on identifying the maximum current configured for being generated by the at least two adjustment battery packs, and performing the preprocessing sequence based on the power of the at least two adjustment battery packs being smaller than or equal to the rated power.

In an exemplary embodiment of the present disclosure, the preprocessing sequence may set states of all relays as ON states by sequentially controlling the relays included in the at least two adjustment battery packs, and may set a state of at least part of the relays as an OFF state based on maintaining states of all the relays as the ON states during a predetermined time period.

The battery control method according to various exemplary embodiments of the present disclosure may include determining whether differences in voltage values between one battery pack included in the at least two adjustment battery packs and the other battery packs other than the one of the at least two adjustment battery packs exceed a first reference value, determining whether at least one of the differences is maintained at the first reference value during a period exceeding a predetermined duration, based on at least one of the differences exceeding the first reference value, and setting states of relays included in the at least two adjustment battery packs as OFF states based on the at least one of the differences being maintained at the first reference value during the period exceeding the predetermined duration.

The battery control method according to various exemplary embodiments of the present disclosure may include determining whether at least one of the differences exceeds a second reference value smaller than the first reference value, based on at least one of the differences being smaller than or equal to the first reference value, and maintaining states of relays included in the at least two adjustment battery packs as current states based on at least one of the differences exceeding the second reference value.

The battery control method according to various exemplary embodiments of the present disclosure may include determining whether at least one of the differences exceeds a third reference value smaller than the second reference value, based on at least one of the differences being smaller than or equal to the second reference value, based on at least one of the differences exceeding the third reference value, maintaining states of relays included in an adjustment battery pack with the greatest voltage value among the at least two adjustment battery packs as current states, setting a state of an anode relay among relays included in an adjustment battery pack with the smallest voltage value among the at least two adjustment battery packs as an ON state, and setting a state of a PC relay among relays included in an adjustment battery pack with the smallest voltage value among the at least two adjustment battery packs as an OFF state.

The battery control method according to various exemplary embodiments of the present disclosure may include, based on at least one of the differences being smaller than or equal to the third reference value, setting a state of an anode relay among relays included in the at least two adjustment battery packs to an ON state, and setting states of PC relays among the relays included in the at least two adjustment battery packs as OFF states.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 shows an example of a block diagram associated with a battery control apparatus, according to an exemplary embodiment of the present disclosure;

FIG. 2 shows an example of supplying power from a battery pack to a drive system, in an exemplary embodiment of the present disclosure;

FIG. 3 shows an example in which charging and discharging between a plurality of battery packs are caused by a battery control apparatus, according to an exemplary embodiment of the present disclosure;

FIG. 4 shows an example of a flowchart associated with a battery control method, according to an exemplary embodiment of the present disclosure;

FIG. 5 shows an example of a flowchart associated with a battery control method, according to an exemplary embodiment of the present disclosure;

FIG. 6 shows an example of a flowchart associated with a battery control method, according to an exemplary embodiment of the present disclosure;

FIG. 7 shows an example of a flowchart associated with a battery control method, according to an exemplary embodiment of the present disclosure;

FIG. 8A, FIG. 8B and FIG. 8C show an example of a flowchart associated with a battery control method, according to an exemplary embodiment of the present disclosure;

FIG. 9 shows an example in which each of battery pack is charged and discharged by relays controlled through a battery control apparatus, according to an exemplary embodiment of the present disclosure;

FIG. 10 shows an example of a flowchart associated with a battery control method, according to an exemplary embodiment of the present disclosure; and

FIG. 11 shows a computing system associated with a battery control apparatus or battery control method, according to an exemplary embodiment of the present disclosure.

It may be understood that the appended drawings are not necessarily to scale, presenting a somewhat simplified representation of various features illustrative of the basic principles of the present disclosure. The specific design features of the present disclosure as included herein, including, for example, specific dimensions, orientations, locations, and shapes locations, and shapes will be determined in part by the particularly intended application and use environment.

In the figures, reference numbers refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Hereinafter, various exemplary embodiments of the present disclosure will be described in detail with reference to the accompanying drawings. In adding reference numerals to components of each drawing, it should be noted that the same components include the same reference numerals, although they are indicated on another drawing. Furthermore, in describing the exemplary embodiments of the present disclosure, detailed descriptions associated with well-known functions or configurations will be omitted if they may make subject matters of the present disclosure unnecessarily obscure.

In describing elements of an exemplary embodiment of the present disclosure, the terms first, second, A, B, (a), (b), and the like may be used herein. These terms are only used to distinguish one element from another element, but do not limit the corresponding elements irrespective of the nature, order, or priority of the corresponding elements. Furthermore, unless otherwise defined, all terms including technical and scientific terms used herein are to be interpreted as is customary in the art to which the present disclosure belongs. It will be understood that terms used herein should be interpreted as including a meaning which is consistent with their meaning in the context of the present disclosure and the relevant art and will not be interpreted in an idealized or overly formal sense unless so defined herein.

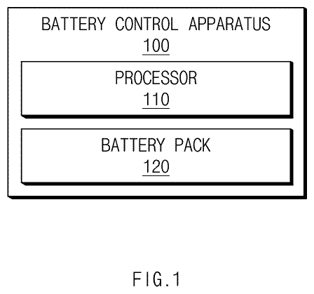

Hereinafter, various embodiments of the present disclosure will be described in detail with reference to FIGS. 1 to 11.

FIG. 1 shows an example of a block diagram associated with a battery control apparatus, according to an exemplary embodiment of the present disclosure.

Referring to FIG. 1, a battery control apparatus 100 according to an exemplary embodiment of the present disclosure may be implemented inside or outside a vehicle, and some of components included in the battery control apparatus 100 may be implemented inside or outside the vehicle. At the instant time, the battery control apparatus 100 may be integrated with internal control units of a vehicle and may be implemented with a separate device to be coupled with control units of the vehicle by a separate connection means. For example, the battery control apparatus 100 may further include components not shown in FIG. 1.

The battery control apparatus 100 according to various exemplary embodiments of the present disclosure may include a processor 110 and a battery pack 120. The processor 110 or the battery pack 120 may be electrically and/or operably coupled with each other by an electronic component including a communication bus.

Hereinafter, the fact that pieces of hardware are coupled operably may include the fact that a direct and/or indirect connection between the pieces of hardware is established by wired and/or wirelessly so that second hardware is controlled by first hardware among the pieces of hardware.

Although different blocks are shown, an exemplary embodiment of the present disclosure is not limited thereto. Some of the pieces of hardware in FIG. 1 may be included in a single integrated circuit including a system on a chip (SoC). The type and/or number of hardware included in the battery control apparatus 100 is not limited to that shown in FIG. 1. For example, the battery control apparatus 100 may include only some of the pieces of hardware shown in FIG. 1.

The battery control apparatus 100 according to various exemplary embodiments of the present disclosure may include a hardware component for processing data based on one or more instructions. The hardware for processing data may include an arithmetic and logic unit (ALU), a floating point unit (FPU), a field programmable gate array (FPGA), a central processing unit (CPU), and/or an application processor (AP). The processor 110 may include a structure of a single-core processor, or may include a structure of a multi-core processor including a dual core, a quad core, a hexa core, or an octa core.

The battery pack 120 included in the battery control apparatus 100 according to various exemplary embodiments of the present disclosure may supply power to at least one component. According to an exemplary embodiment of the present disclosure, the battery pack 120 may include a primary cell not rechargeable, a secondary cell rechargeable, and/or a fuel cell.

In an exemplary embodiment of the present disclosure, the battery pack 120 may include a plurality of relays, and/or resistors. Although the battery pack 120 is described in the present disclosure, the battery pack 120 described in the present disclosure may include a battery system assembly (BSA).

For example, each of the relays included in the battery pack 120 may include components for controlling electrical signals and/or power output from the battery pack 120. For example, the plurality of relays included in the battery pack 120 may be referred to as “switches”.

For example, the battery pack 120 may include at least two relays. For example, the battery pack 120 may include a first relay, a second relay, and/or a third relay. For example, the battery pack 120 may include an anode relay, a cathode relay, and/or a pre-charge (PC) relay. However, an exemplary embodiment of the present disclosure is not limited to the above description.

Moreover, the battery pack 120 may include a controller and/or a sensor. For example, the controller included in the battery pack 120 may include a battery management unit (BMU) and/or a cell monitoring unit (CMU).

For example, the sensor included in the battery pack 120 may transmit sensor data based on the voltage and/or current of the battery pack 120 to the processor 110. The processor 110 receiving the sensor data based on the voltage and/or current of the battery pack 120 may measure the voltage and/or current of the battery pack 120.

In an exemplary embodiment of the present disclosure, the battery control apparatus 100 and/or the battery pack 120 may include a pre-charge resistor (PC.R). For example, the resistor included in the battery control apparatus 100 and/or the battery pack 120 may include a component for controlling the current output from the battery pack 120.

The battery control apparatus 100 according to various exemplary embodiments of the present disclosure may further include a memory. For example, one or more instructions (or instructions) indicating an arithmetic operation and/or an operation to be performed on data by the processor 110 of the battery control apparatus 100 may be stored in the memory 120.

A set of one or more instructions may be referred to as a “program”, “firmware”, an “operating system”, a “process”, a “routine”, a “sub-routine”, and/or an “application”.

Hereinafter, the fact that an application is provided in the battery control apparatus 100 may mean that the one or more instructions provided in a form of an application are stored in the memory, and may mean that one or more applications are stored in a format (e.g., a file with an extension designated by the operating system of the battery control apparatus 100) which is executable by the processor 110 of the battery control apparatus 100.

The processor 110 of the battery control apparatus 100 according to various exemplary embodiments of the present disclosure may obtain voltage values respectively corresponding to a plurality of battery packs. The processor 110 may be configured to determine the target voltage of voltage values based on obtaining the voltage values respectively corresponding to the plurality of battery packs.

For example, the processor 110 may be configured to determine the target voltage for balancing voltage values of the plurality of battery packs.

In an exemplary embodiment of the present disclosure, the processor 110 may identify at least two adjustment battery packs for adjusting a voltage value among a plurality of battery packs based on comparing the target voltage with the voltage values respectively corresponding to the plurality of battery packs.

For example, the processor 110 may set states of a plurality of relays included in the plurality of battery packs as OFF states. For example, the processor 110 may set states of all the plurality of relays included in the plurality of battery packs as the OFF states.

The processor 110 may be configured to determine an average value based on storing the voltage values respectively corresponding to the plurality of battery packs. The processor 110 may set the determined average value to the target voltage for identifying at least two adjustment battery packs.

In an exemplary embodiment of the present disclosure, the processor 110 may compare the target voltage with each of voltage values respectively corresponding to the plurality of battery packs.

For example, the processor 110 may identify a battery pack, of which a voltage value is within a predetermined range including the target voltage, based on comparing the target voltage with the voltage values respectively corresponding to the plurality of battery packs. The processor 110 may classify a battery pack with a voltage value within a predetermined range including the target voltage as a first group. For example, the first group described in FIG. 1 may be referred to as a medium voltage (VP.MV).

For example, the processor 110 may classify a battery pack with a voltage value, which exceeds a first value from the target voltage, from among the plurality of battery packs as a second group. For example, the first value may include approximately +1 V.

For example, the processor 110 may classify a battery pack, of which a voltage value is smaller than a second value from the target voltage, from among the plurality of battery packs as a third group. For example, the second value may include approximately −1 V.

In an exemplary embodiment of the present disclosure, the processor 110 may identify battery packs included in at least one of the second group, or the third group, or any combination thereof as at least two adjustment battery packs.

In an exemplary embodiment of the present disclosure, the processor 110 may obtain difference values between the target voltage and each of voltage values based on comparing the target voltage with each of the voltage values respectively corresponding to the plurality of battery packs. The processor 110 may store difference values based on sorting the difference values between the target voltage and each of voltage values in the designated sorting method. For example, the designated sorting method may include at least one of ascending order, or descending order, or any combination thereof.

For example, the processor 110 may execute a preprocessing sequence based on the order of difference values.

In an exemplary embodiment of the present disclosure, the processor 110 may identify the maximum current configured for being generated by at least two adjustment battery packs. The processor 110 may be configured to determine whether the power of at least two adjustment battery packs generated by the maximum current exceeds the rated power of a resistor, based on identifying the maximum current configured for being generated by the at least two adjustment battery packs. The processor 110 may execute the preprocessing sequence based on the power of at least two adjustment battery packs being smaller than or equal to the rated power.

For example, the preprocessing sequence may include a function of setting states of all relays as ON states by sequentially controlling relays included in the at least two adjustment battery packs. For example, the preprocessing sequence may include a function of setting the state of at least part of the relays as an OFF state based on maintaining states of all relays as ON states during a predetermined time period.

In an exemplary embodiment of the present disclosure, the processor 110 may execute a preprocessing sequence for battery balancing on the at least two adjustment battery packs. The processor 110 may perform a balancing charging and discharging sequence for adjusting voltage values of the at least two adjustment battery packs to the target voltage, based on performing the preprocessing sequence for battery balancing on the at least two adjustment battery packs.

In an exemplary embodiment of the present disclosure, the processor 110 may adjust the voltage values of the at least two adjustment battery packs within a predetermined range including the target voltage based on the balancing charging and discharging sequence.

For example, the predetermined range may include a range of ‘+/−0.01’ from the target voltage.

In an exemplary embodiment of the present disclosure, the processor 110 may be configured to determine whether differences in voltage values between any one battery pack included in the at least two adjustment battery packs and other battery packs other than the one of the at least two adjustment battery packs exceed a first reference value. The processor 110 may be configured to determine whether at least one of the differences is maintained at a first reference value during a period exceeding the designated duration, based on at least one of the differences exceeding the first reference value. The processor 110 may set states of relays included in the at least two adjustment battery packs as OFF states based on at least one of the differences being maintained at the first reference value during a period exceeding the designated duration.

In an exemplary embodiment of the present disclosure, the processor 110 may be configured to determine whether the at least one of the differences in voltage values of battery packs other than the one of at least two adjustment battery packs exceeds a second reference value smaller than the first reference value, based on the at least one of the differences in voltage values of battery packs other than the one of the at least two adjustment battery packs being smaller than or equal to the first reference value. The processor 110 may maintain states of relays included in the at least two adjustment battery packs as current states based on at least one of the differences exceeding the second reference value.

In an exemplary embodiment of the present disclosure, the processor 110 may be configured to determine whether the at least one of the differences exceeds a third reference value smaller than the second reference value, based on the at least one of the differences in voltage values of battery packs other than the one of the at least two adjustment battery packs being smaller than or equal to the second reference value. The processor 110 may maintain the states of the relays included in the adjustment battery pack with the greatest voltage value among the at least two adjustment battery packs based on the at least one of the differences exceeding the third reference value. The processor 110 may set the state of an anode relay among relays included in an adjustment battery pack with the smallest voltage value among the at least two adjustment battery packs as an ON state, based on the at least one of the differences exceeding the third reference value.

In an exemplary embodiment of the present disclosure, the processor 110 may set the state of a PC relay among the relays included in the adjustment battery pack with the smallest voltage value among the at least two adjustment battery packs as an OFF state, based on the at least one of the differences in voltage values of battery packs other than the one of at least two adjustment battery packs exceeding the third reference value.

In an exemplary embodiment of the present disclosure, the processor 110 may set the state of the anode relay among the relays included in the at least two adjustment battery packs as the ON state, based on the at least one of the differences in voltage values of battery packs other than the one of at least two adjustment battery packs being smaller than or equal to the third reference value. The processor 110 may set states of PC relays among the relays included in the at least two adjustment battery packs as the OFF state, based on the at least one of the differences in voltage values of battery packs other than the one of at least two adjustment battery packs being smaller than or equal to the third reference value.

As described above, the battery control apparatus 100 according to various exemplary embodiments of the present disclosure may perform balancing on a plurality of battery packs by performing the above operations. The battery control apparatus 100 may perform balancing by controlling relays included in a plurality of battery packs, reducing related facility investment costs by performing pack balancing without an external charger. Moreover, the battery control apparatus 100 may shorten the balancing time by simultaneously applying a great balancing current and charging and/or discharging battery packs compared to cell balancing.

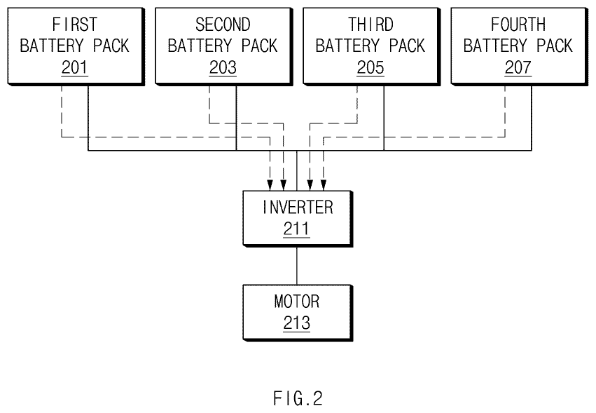

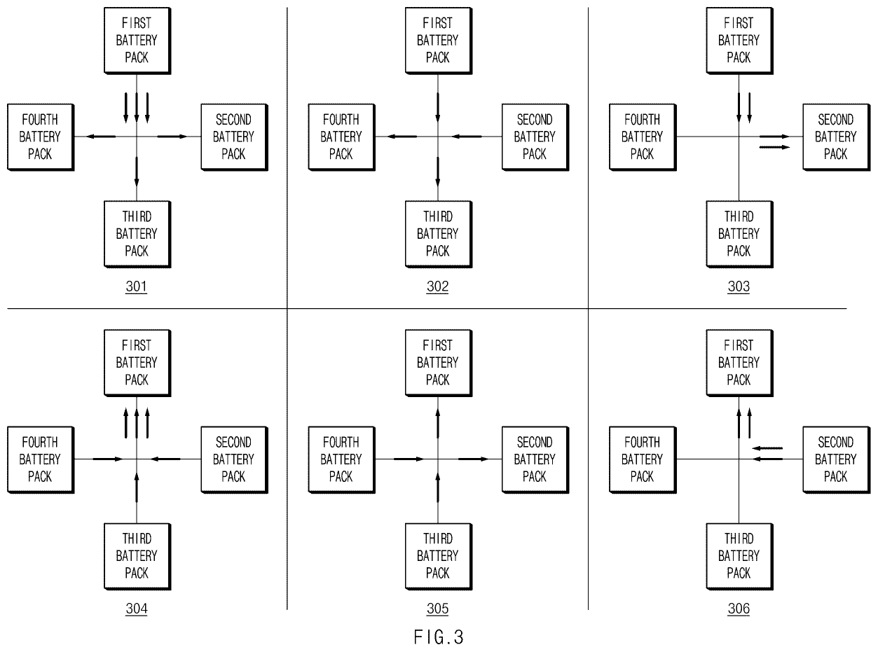

FIG. 2 shows an example of supplying power from a battery pack to a drive system, in an exemplary embodiment of the present disclosure.

Referring to FIG. 2, battery packs 201, 203, 205, and 207 may be connected in parallel to each other. For example, the first battery pack 201, the second battery pack 203, the third battery pack 205, and/or the fourth battery pack 207 may be connected in parallel to supply power to a drive system.

For example, the drive system may include an inverter 211 and/or a motor 213. A vehicle including the battery packs 201, 203, 205, and 207, the inverter 211, and/or the motor 213 may use the electrical energy provided from the battery packs 201, 203, 205, and 207 in a form of electrical energy. Alternatively, the vehicle may convert the electrical energy provided from the battery packs 201, 203, 205, and 207 into other energy to drive the inverter 211 and/or the motor 213.

FIG. 3 shows an example in which charging and discharging between a plurality of battery packs are caused by a battery control apparatus, according to an exemplary embodiment of the present disclosure.

Referring to FIG. 3, a battery control apparatus (e.g., the battery control apparatus 100 in FIG. 1) according to various exemplary embodiments of the present disclosure may be configured for controlling relays connecting a plurality of battery packs (e.g., a first battery pack, a second battery pack, a third battery pack, and/or a fourth battery pack). For example, an operation of controlling relays may include controlling a power relay assembly (PRA).

Examples 301, 302, 303, 304, 305, and 306 in FIG. 3 may include examples in which a battery pack with a relatively high voltage is discharged, and at the same time, a battery pack with a relatively low voltage is charged, depending on the voltage of each battery pack.

The first example 301 of FIG. 3 may include an example in which the voltage of the first battery pack is higher than voltages of the second battery pack, the third battery pack, and the fourth battery pack. In the first example 301, because the voltage of the first battery pack is higher than the voltages of the second battery pack, the third battery pack, and the fourth battery pack, the battery control apparatus may change states of relays configured for connecting the first battery pack, the second battery pack, the third battery pack, and the fourth battery pack to ON states, may cause discharge of the first battery pack, and may cause charging of the second battery pack, the third battery pack, and the fourth battery pack.

The second example 302 of FIG. 3 may include an example in which voltages of the first battery pack and the second battery pack are higher than voltages of the third battery pack and the fourth battery pack. In the second example 302, because the voltages of the first battery pack and the second battery pack are higher than the voltages of the third battery pack and the fourth battery pack, the battery control apparatus may change the states of the relays configured for connecting the first battery pack, the second battery pack, the third battery pack, and the fourth battery pack to ON states, may cause discharge of the first battery pack and the second battery pack, and may cause charging of the third battery pack and the fourth battery pack.

The third example 303 of FIG. 3 may include an example in which the voltage of the first battery pack is higher than the voltage of the second battery pack, and voltages of the third and fourth battery packs correspond to the target voltage. In the third example 303, because the voltage of the first battery pack is higher than the voltage of the second battery pack, and the voltages of the third and fourth battery packs correspond to the target voltage, the battery control apparatus may change the states of the relays configured for connecting the first battery pack and the second battery pack to ON states, may cause discharge of the first battery pack, and may cause charging of the second battery pack.

The fourth example 304 of FIG. 3 may include an example in which the voltage of the first battery pack is lower than the voltages of the second battery pack, the third battery pack, and the fourth battery pack. In the fourth example 304, because the voltage of the first battery pack is lower than the voltages of the second battery pack, the third battery pack, and the fourth battery pack, the battery control apparatus may change states of relays configured for connecting the first battery pack, the second battery pack, the third battery pack, and the fourth battery pack to ON states, may cause discharge of the second battery pack, the third battery pack, and the fourth battery pack, and may cause charging of the first battery pack.

The fifth example 305 of FIG. 3 may include an example in which voltages of the first battery pack and the second battery pack are lower than voltages of the third battery pack and the fourth battery pack. In the fifth example 305, because the voltages of the first battery pack and the second battery pack are lower than the voltages of the third battery pack and the fourth battery pack, the battery control apparatus may change the states of the relays configured for connecting the first battery pack, the second battery pack, the third battery pack, and the fourth battery pack to ON states, may cause discharge of the third battery pack and the fourth battery pack, and may cause charging of the first battery pack and the second battery pack.

The sixth example 306 of FIG. 3 may include an example in which the voltage of the first battery pack is lower than the voltage of the second battery pack, and voltages of the third and fourth battery packs correspond to the target voltage. In the sixth example 306, because the voltage of the first battery pack is lower than the voltage of the second battery pack, and the voltages of the third and fourth battery packs correspond to the target voltage, the battery control apparatus may change the states of the relays configured for connecting the first battery pack and the second battery pack to ON states, may cause discharge of the second battery pack, and may cause charging of the first battery pack.

As described above, the battery control apparatus according to various exemplary embodiments of the present disclosure may cause charging and/or discharging of battery packs by controlling relays configured for electrically connecting battery packs. The battery control apparatus may cause voltages of the battery packs to be adjusted to the target voltage by causing charging and/or discharging of the battery packs based on controlling the relays.

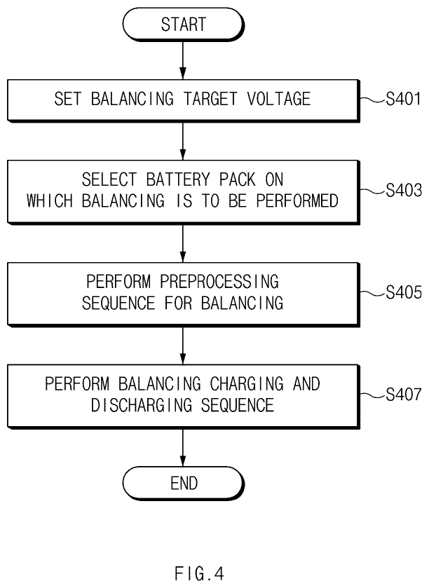

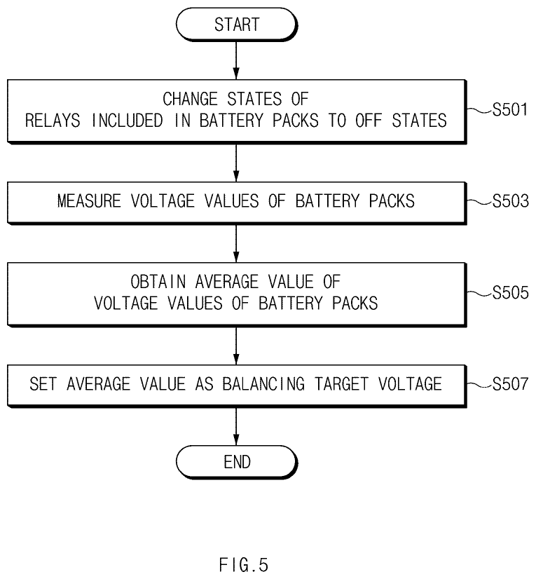

FIG. 4 shows an example of a flowchart associated with a battery control method, according to an exemplary embodiment of the present disclosure.

Hereinafter, it is assumed that the battery control apparatus 100 of FIG. 1 is configured to perform the process of FIG. 4. Furthermore, in a description of FIG. 4, it may be understood that an operation described as being performed by an apparatus is controlled by the processor 110 of the battery control apparatus 100.

At least one of operations of FIG. 4 may be performed by the battery control apparatus 100 of FIG. 1. At least one of operations of FIG. 4 may be performed by the processor 110 of FIG. 1. Each of the operations in FIG. 4 may be performed sequentially, but is not necessarily sequentially performed. For example, the order of operations may be changed, and at least two operations may be performed in parallel.

Referring to FIG. 4, in S401, a battery control method according to various exemplary embodiments of the present disclosure may include an operation of setting a balancing target voltage.

For example, the battery control method may include an operation of setting (or determining) the balancing target voltage based on monitoring current states of battery packs. Details associated with the operation of setting the balancing target voltage are described later in FIG. 5.

In S403, the battery control method according to various exemplary embodiments of the present disclosure may include an operation of selecting a battery pack on which balancing is to be performed.

For example, the battery control method may include an operation of identifying a battery pack requiring balancing and/or a battery pack not requiring balancing based on the current voltage of the battery pack.

Moreover, the battery control method may classify battery packs by grouping the battery packs requiring balancing and/or battery packs not requiring balancing.

In S405, the battery control method according to various exemplary embodiments of the present disclosure may include an operation of performing a preprocessing sequence for balancing.

For example, the battery control method may include an operation of performing the preprocessing sequence associated with whether it is safe to perform balancing in terms of the rated power of a resistor.

For example, the battery control method may include an operation of sequentially controlling relays to safely connect all battery packs to a high-voltage path.

In S407, the battery control method according to various exemplary embodiments of the present disclosure may include an operation of performing a balancing charging and discharging sequence.

For example, the battery control method may include an operation of controlling relays included in battery packs to prevent accidents from occurring in terms of the rated power of a resistor. For example, the battery control method may include an operation of performing a balancing charging and discharging sequence for adjusting voltages of battery packs within the limit of not exceeding the rated power of the resistor.

The battery control method according to various exemplary embodiments of the present disclosure may include an operation of terminating the balancing charging and discharging sequence based on the fact that the voltage value of each of battery packs is adjusted to a value within a predetermined range including the target voltage.

FIG. 5 shows an example of a flowchart associated with a battery control method, according to an exemplary embodiment of the present disclosure.

Hereinafter, it is assumed that the battery control apparatus 100 of FIG. 1 is configured to perform the process of FIG. 5. Furthermore, in a description of FIG. 5, it may be understood that an operation described as being performed by an apparatus is controlled by the processor 110 of the battery control apparatus 100.

At least one of operations of FIG. 5 may be performed by the battery control apparatus 100 of FIG. 1. At least one of operations of FIG. 5 may be performed by the processor 110 of FIG. 1. Each of the operations in FIG. 5 may be performed sequentially, but is not necessarily sequentially performed. For example, the order of operations may be changed, and at least two operations may be performed in parallel.

Operations of FIG. 5 may be included in S401 of FIG. 4.

Referring to FIG. 5, in S501, the battery control method according to various exemplary embodiments of the present disclosure may include an operation of changing states of all relays included in battery packs to OFF states.

For example, the battery control method may include changing the states of all relays to OFF states so that there are no relays in ON states. For example, the fact that the state of a relay is an ON state may mean a state where one end portion and the other end portion of the relay are connected to a conducting wire. For example, the fact that the state of the relay is OFF state, it may mean a state where at least one of one end portion and the other end portion of the relay is not connected to the conducting wire.

In S503, the battery control method according to various exemplary embodiments of the present disclosure may include an operation of measuring voltage values of battery packs.

For example, the battery control method may include an operation of sequentially measuring the voltages of the battery packs.

For example, the battery control method may include an operation of storing the measured voltage values based on measuring the voltage values of the battery packs. For example, the battery control method may include an operation of storing the measured voltage values in variables.

In S505, the battery control method according to various exemplary embodiments of the present disclosure may include an operation of obtaining an average value of the voltage values of the battery packs.

For example, the battery control method may include an operation of summing the voltage values of the battery packs. The battery control method may include an operation of determining an average value based on summing the voltage values of the battery packs.

In S507, the battery control method according to various exemplary embodiments of the present disclosure may include an operation of setting the average value obtained in S505 as the target voltage.

For example, the battery control method may include an operation of setting the target voltage, which causes balancing termination, to the average value of the voltage values of the battery packs.

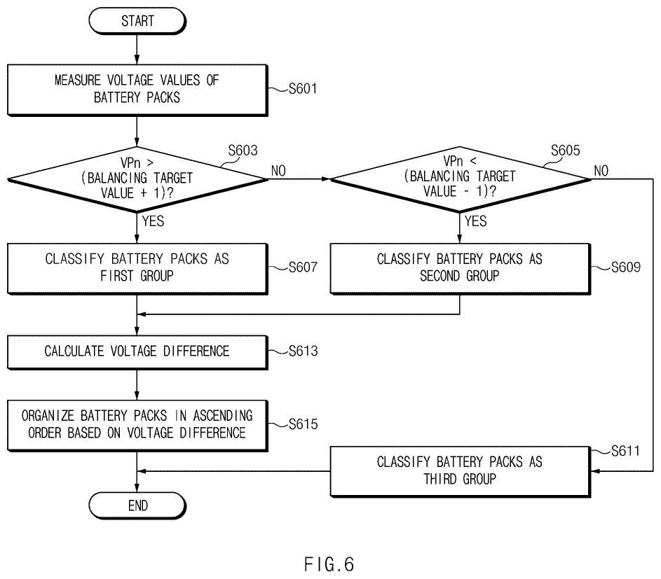

FIG. 6 shows an example of a flowchart associated with a battery control method, according to an exemplary embodiment of the present disclosure.

Hereinafter, it is assumed that the battery control apparatus 100 of FIG. 1 is configured to perform the process of FIG. 6. Furthermore, in a description of FIG. 6, it may be understood that an operation described as being performed by an apparatus is controlled by the processor 110 of the battery control apparatus 100.

At least one of operations of FIG. 6 may be performed by the battery control apparatus 100 of FIG. 1. At least one of operations of FIG. 6 may be performed by the processor 110 of FIG. 1. Each of the operations in FIG. 6 may be performed sequentially, but is not necessarily sequentially performed. For example, the order of operations may be changed, and at least two operations may be performed in parallel.

Operations of FIG. 6 may be included in S403 of FIG. 4.

Referring to FIG. 6, in S601, the battery control method according to various exemplary embodiments of the present disclosure may include an operation of measuring voltage values of battery packs.

In S603, the battery control method according to various exemplary embodiments of the present disclosure may include an operation of determining whether VPn exceeds ‘balancing target value +1’. For example, the VPn may refer to the voltage value of each of the battery packs. For example, the balancing target value may include a target voltage. For example, VP1 may mean a voltage value of a first battery. For example, VP2 may mean a voltage value of a second battery. As described above, ‘n’ in the VPn may mean the number for identifying a battery. However, various exemplary embodiments of the present disclosure are not limited to the above description.

If the VPn does not exceed ‘balancing target value +1’ (No in S603), in S605, the battery control method according to various exemplary embodiments of the present disclosure may include an operation of determining whether the VPn is smaller than ‘balancing target value −1’.

If the VPn exceeds ‘balancing target value +1’ (Yes in S603), in S607, the battery control method according to various exemplary embodiments of the present disclosure may include an operation of classifying battery packs as a first group. For example, the battery control method may include an operation of classifying a battery pack whose VPn exceeds ‘balancing target value +1’ as the first group. For example, the first group may be referred to as a high voltage (VP.HV).

If the VPn is smaller than ‘balancing target value −1’ (Yes in S605), in S609, the battery control method according to various exemplary embodiments of the present disclosure may include an operation of classifying battery packs as a second group. For example, the battery control method may include an operation of classifying a battery pack whose VPn is smaller than ‘balancing target value −1’ as the second group. For example, the second group may be referred to as a low voltage (VP.LV).

If The VPn is not smaller than ‘balancing target value −1’ (No in S605), in S611, the battery control method according to various exemplary embodiments of the present disclosure may include an operation of classifying battery packs as a third group. For example, the battery control method may include an operation of classifying battery packs whose VPn is not smaller than ‘balancing target value −1’ as the third group. For example, the third group may be referred to as a medium voltage (VP.MV).

The battery control method may include an operation of identifying the first group and the second group among the above-mentioned first group, second group, and third group as groups requiring balancing.

In S613, the battery control method according to various exemplary embodiments of the present disclosure may include an operation of determining a voltage difference. For example, the battery control method may include an operation of determining the difference between a voltage value of battery packs classified as the first group and a voltage value of battery packs classified as the second group.

For example, the battery control method may include an operation of determining the voltage difference based on Equation 1 below.

$$Δ VPn = VPn - VPref \qquad [ Equation 1 ]$$

For example, in Equation 1, ΔVPn may denote a voltage difference. In Equation 1, VPn may denote the voltage of the n-th battery pack. In Equation 1, VPref may denote a target voltage.

In S615, the battery control method according to various exemplary embodiments of the present disclosure may include an operation of organizing battery packs in ascending order based on the voltage difference.

For example, the battery control method may include sorting battery packs in ascending order based on the voltage difference, based on the voltage difference obtained by Equation 1.

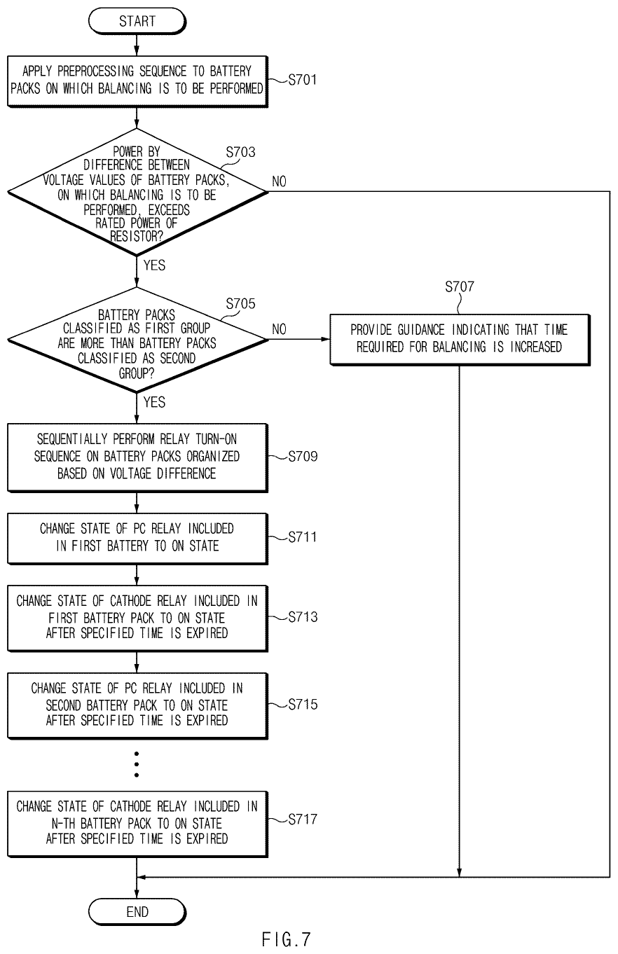

FIG. 7 shows an example of a flowchart associated with a battery control method, according to an exemplary embodiment of the present disclosure.

Hereinafter, it is assumed that the battery control apparatus 100 of FIG. 1 is configured to perform the process of FIG. 7. Furthermore, in a description of FIG. 7, it may be understood that an operation described as being performed by an apparatus is controlled by the processor 110 of the battery control apparatus 100.

At least one of operations of FIG. 7 may be performed by the battery control apparatus 100 of FIG. 1. At least one of operations of FIG. 7 may be performed by the processor 110 of FIG. 1. Each of the operations in FIG. 7 may be performed sequentially, but is not necessarily sequentially performed. For example, the order of operations may be changed, and at least two operations may be performed in parallel.

Operations of FIG. 7 may be included in S405 of FIG. 4.

Referring to FIG. 7, in $701, the battery control method according to various exemplary embodiments of the present disclosure may include an operation of applying a preprocessing sequence to battery packs on which balancing is to be performed. For example, the battery packs on which balancing is to be performed may include battery packs classified into the first group and second group by the operations described in FIG. 6.

In S703, the battery control method according to various exemplary embodiments of the present disclosure may include an operation of determining whether the power by a difference between voltage values of battery packs, on which balancing is to be performed, exceeds the rated power of a resistor.

In S705, the battery control method according to various exemplary embodiments of the present disclosure may include an operation of determining whether battery packs classified as the first group are more than battery packs classified as the second group.

In S707, the battery control method according to various exemplary embodiments of the present disclosure may include an operation of providing guidance indicating that a time required for balancing may be increased.

In S709, the battery control method according to various exemplary embodiments of the present disclosure may include an operation of sequentially performing a relay turn-on sequence on battery packs organized based on a voltage difference.

In S711, the battery control method according to various exemplary embodiments of the present disclosure may include an operation of changing the state of a PC relay included in a first battery to an ON state.

In S713, the battery control method according to various exemplary embodiments of the present disclosure may include an operation of changing the state of a cathode relay included in the first battery pack to an ON state after a designated time is expired.

In S715, the battery control method according to various exemplary embodiments of the present disclosure may include an operation of changing the state of a PC relay included in a second battery pack to an ON state.

In S717, the battery control method according to various exemplary embodiments of the present disclosure may include an operation of changing the state of a cathode relay included in an n-th battery pack to an ON state after a designated time is expired.

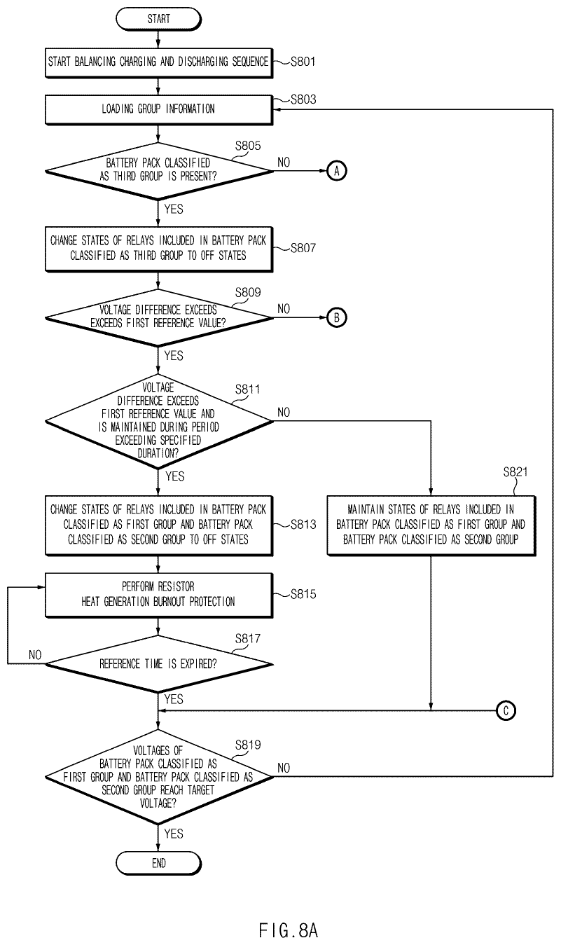

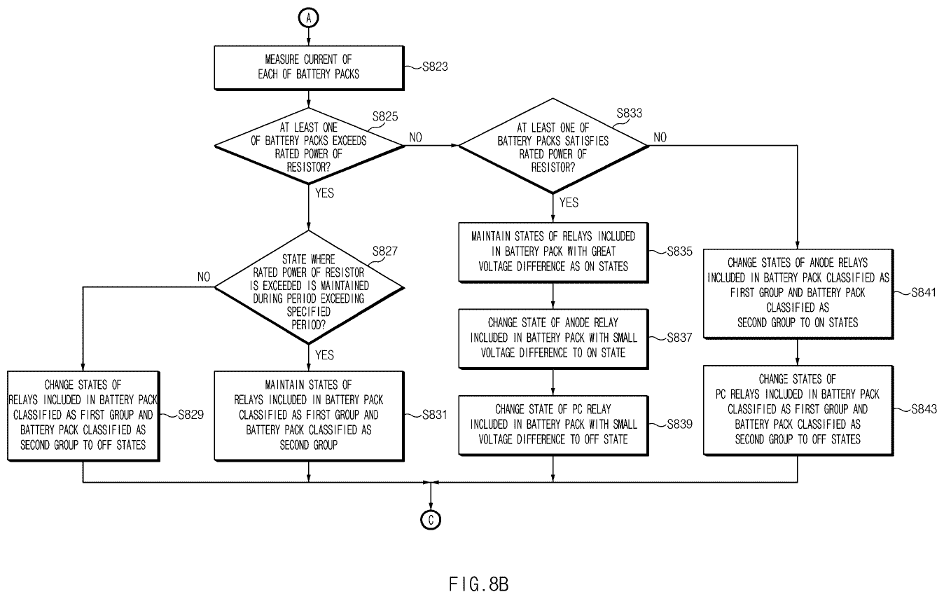

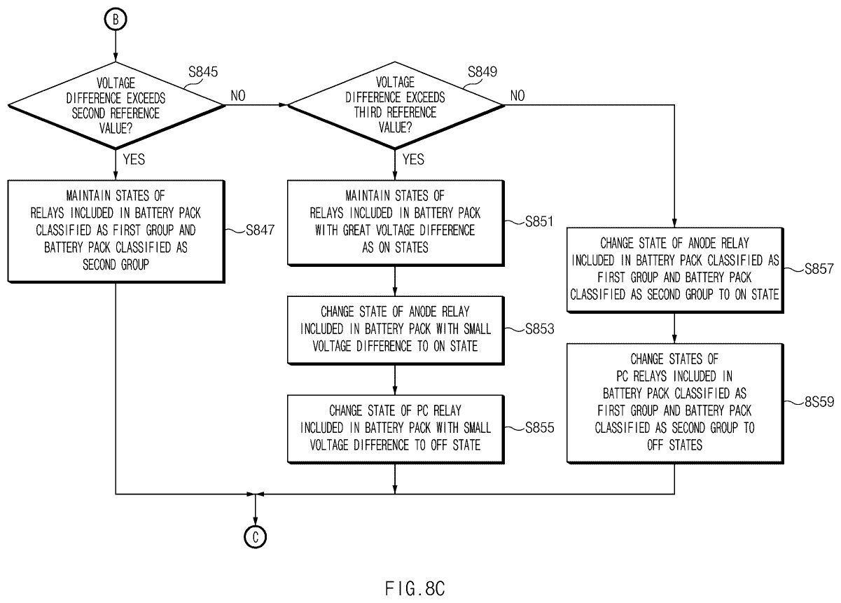

FIG. 8A, FIG. 8B and FIG. 8C show an example of a flowchart associated with a battery control method, according to an exemplary embodiment of the present disclosure.

Hereinafter, it is assumed that the battery control apparatus 100 of FIG. 1 is configured to perform the process of FIG. 8. Furthermore, in a description of FIG. 8, it may be understood that an operation described as being performed by an apparatus is controlled by the processor 110 of the battery control apparatus 100.

At least one of operations of FIG. 8 may be performed by the battery control apparatus 100 of FIG. 1. At least one of operations of FIG. 8 may be performed by the processor 110 of FIG. 1. Each of the operations in FIG. 8 may be performed sequentially, but is not necessarily sequentially performed. For example, the order of operations may be changed, and at least two operations may be performed in parallel.

Operations of FIG. 8A, FIG. 8B and FIG. 8C may be included in S407 of FIG. 4.

Referring to FIG. 8A, in S801, the battery control method according to various exemplary embodiments of the present disclosure may include an operation of starting a balancing charging and discharging sequence.

For example, the operations described below may be included in the balancing charging and discharging sequence.

In S803, the battery control method according to various exemplary embodiments of the present disclosure may include an operation of loading group information.

For example, the battery control method may include an operation of loading the group information indicating battery packs classified into a first group, a second group, and/or a third group.

In S805, the battery control method according to various exemplary embodiments of the present disclosure may include an operation of determining whether a battery pack classified as the third group is present.

For example, the third group may refer to a group of battery packs not requiring balancing. For example, the third group may be referred to as VP.MV.

If there is a battery pack classified as third group (Yes in S805), in S807, the battery control method according to various exemplary embodiments of the present disclosure may include an operation of changing states of relays included in a battery pack classified as the third group to OFF states.

For example, the battery control method may include an operation of setting the states of relays included in the battery pack classified as the third group as the OFF states.

In S809, the battery control method according to various exemplary embodiments of the present disclosure may include an operation of determining whether a voltage difference exceeds a first reference value.

For example, the voltage difference may be obtained based on Equation 2 below.

$$ΔV = VP . HV - VP . LV \qquad [ Equation 2 ]$$

In Equation 2, ΔV may denote a voltage difference. In Equation 2, VP.HV may denote the voltage of a battery pack classified as the first group. In Equation 2, VP.LV may denote the voltage of the battery pack classified as the second group.

For example, the battery control method may include an operation of determining whether a voltage difference exceeds a first reference value, based on Equation 3 below.

$$( \frac{ΔV}{2 R} ) > 1.4 ( A ) \qquad [ Equation 3 ]$$

For example, in Equation 3, 2R may denote a resistance value of two resistors. For example, in Equation 3, 1.4(A) may denote 1.4 amperes. Equation 3 may include an equation for determining whether the rated power of 2R is exceeded.

In S811, the battery control method according to various exemplary embodiments of the present disclosure may include an operation of determining whether the voltage difference exceeds the first reference value and is maintained during a period exceeding the designated duration.

For example, the designated duration may include approximately 5 seconds.

If the voltage difference exceeds the first reference value and is maintained during the period exceeding the designated duration (Yes in S811), in S813, the battery control method according to various exemplary embodiments of the present disclosure may include an operation of changing states of relays included in the battery pack classified as the first group and the battery pack classified as the second group to OFF states.

For example, the battery control method may include an operation of setting the states of relays included in the battery pack classified as the first group and the battery pack classified as the second group as the OFF states.

In S815, the battery control method according to various exemplary embodiments of the present disclosure may include an operation of performing resistor heat generation burnout protection.

For example, the battery control method may include an operation of performing resistor heat burnout protection to prevent damage due to heat generated by a resistor.

In S817, the battery control method according to various exemplary embodiments of the present disclosure may include an operation of determining whether a reference time is expired.

For example, the reference time may include approximately 10 minutes.

In S819, the battery control method according to various exemplary embodiments of the present disclosure may include an operation of determining whether voltages of the battery pack classified as the first group and the battery pack classified as the second group reach the target voltage.

If the voltages of the battery pack classified as the first group and the battery pack classified as the second group do not reach the target voltage (No in S819), the battery control method according to various exemplary embodiments of the present disclosure may include an operation of returning to S803 and loading group information.

If the voltages of the battery pack classified as first group and the battery pack classified as second group reach the target voltage (Yes in S819), the battery control method according to various exemplary embodiments of the present disclosure may include an operation of terminating the balancing charging and discharging sequence.

If the voltage difference exceeds the first reference value and is not maintained during the period exceeding the designated duration (No in S811), in S821, a battery control method according to various exemplary embodiments of the present disclosure may include an operation of maintaining states of relays included in a battery pack classified as the first group and a battery pack classified as the second group.

If the battery pack classified as the third group is not present (No in S805), in S823, a battery control method according to various exemplary embodiments of the present disclosure may include an operation of measuring the current of each of battery packs.

In S825, the battery control method according to various exemplary embodiments of the present disclosure may include an operation of determining whether at least one of battery packs exceeds the rated power of the resistor.

For example, the battery control method may include an operation of determining whether at least one of the battery packs exceeds the rated power of the resistor, based on Equation 4 below.

$$In > 1.4 ( A ) \qquad [ Equation 4 ]$$

In Equation 4, In may denote the current of the n-th battery. In Equation 4, 1.4(A) may denote 1.4 amperes.

If at least one of the battery packs exceeds the rated power of the resistor (Yes in S825), in S827, the battery control method according to various exemplary embodiments of the present disclosure may include an operation of determining whether a state where the rated power of the resistor is exceeded is maintained during a period exceeding a designated period.

For example, the designated time may include approximately 5 seconds. For example, the state where the rated power of the resistor is exceeded may be identified based on Equation 4. For example, the state where the rated power of the resistor is exceeded may mean satisfying Equation 4 above.

If the state exceeding the rated power of the resistor is not maintained during the period exceeding the designated period (No in S827), in S829, the battery control method according to various exemplary embodiments of the present disclosure may include an operation of changing the states of relays included in the battery pack classified as the first group and the battery pack classified as the second group to the OFF states.

For example, the battery control method may include an operation of setting the states of relays included in the battery pack classified as the first group and the battery pack classified as the second group as the OFF states.

If the state exceeding the rated power of the resistor is maintained during the period exceeding the designated period (Yes in S827), in S831, the battery control method according to various exemplary embodiments of the present disclosure may include an operation of maintaining the states of relays included in the battery pack classified as the first group and the battery pack classified as the second group.

For example, the battery control method may include an operation of maintaining states of the relays included in the battery pack classified as the first group and the battery pack classified as the second group as existing states without separate settings.

If at least one of the battery packs does not exceed the rated power of the resistor (No in S825), in S833, the battery control method according to various exemplary embodiments of the present disclosure may include an operation of determining whether at least one of the battery packs satisfies the rated power of a resistor.

For example, the battery control method may include an operation of determining whether at least one of the battery packs satisfies the rated power of the resistor, based on Equation 5 below.

$$In > 0.7 ( A ) \qquad [ Equation 5 ]$$

In Equation 5, In may denote the current of the n-th battery pack. In Equation 5, 0.7(A) may denote 0.7 amperes.

If at least one of the battery packs satisfies the rated power of the resistor (Yes in S833), in S835, the battery control method according to various exemplary embodiments of the present disclosure may include an operation of maintaining states of relays included in a battery pack with a great voltage difference as ON states.

For example, the battery control method may include an operation of setting states of relays included in a battery pack with a great voltage difference as ON states.

In S837, the battery control method according to various exemplary embodiments of the present disclosure may include an operation of changing the state of an anode relay included in a battery pack with a small voltage difference to an ON state.

For example, the battery control method may include an operation of setting the state of the anode relay included in the battery pack with a small voltage difference as the ON state.

In S839, the battery control method according to various exemplary embodiments of the present disclosure may include an operation of changing the state of a PC relay included in a battery pack with a small voltage difference to the OFF state.

For example, the battery control method may include an operation of setting the state of the PC relay included in the battery pack with a small voltage difference as the OFF state.

If at least one of the battery packs does not meet the rated power of the resistor (No in S833), in S841, the battery control method according to various exemplary embodiments of the present disclosure may include an operation of changing states of anode relays included in the battery pack classified as the first group and the battery pack classified as the second group to ON states.

For example, the battery control method may include an operation of setting the states of the anode relays included in the battery pack classified as the first group and the battery pack classified as the second group as the ON states.

In S843, the battery control method according to various exemplary embodiments of the present disclosure may include an operation of changing states of PC relays included in the battery pack classified as the first group and the battery pack classified as the second group to OFF states.

For example, the battery control method may include an operation of setting the states of the PC relays included in the battery pack classified as the first group and the battery pack classified as the second group as the OFF states.

If the voltage difference does not exceed the first reference value (No in S809), in S845, the battery control method according to various exemplary embodiments of the present disclosure may include an operation of determining whether the voltage difference exceeds a second reference value.

For example, the battery control method may include an operation of determining whether the voltage difference exceeds the second reference value, based on Equation 6 below.

$$( \frac{ΔV}{2 R} ) > 0.7 ( A ) \qquad [ Equation 6 ]$$

In Equation 6, ΔV may denote a voltage difference. In Equation 6, 2R may denote the resistance value of two resistors. In Equation 6, 0.7(A) may denote 0.7 amperes.

If the voltage difference exceeds the second reference value (Yes in S845), in S847, the battery control method according to various exemplary embodiments of the present disclosure may include an operation of maintaining the states of relays included in the battery pack classified as the first group and the battery pack classified as the second group.

For example, the battery control method may include an operation of maintaining the states of the relays included in the battery pack classified as the first group and the battery pack classified as the second group as the existing states without separate settings.

If the voltage difference does not exceed the second reference value (No in S845), in S849, the battery control method according to various exemplary embodiments of the present disclosure may include an operation of determining whether the voltage difference exceeds a third reference value.

For example, the battery control method may include an operation of determining whether the voltage difference exceeds the third reference value, based on Equation 7 below.

$$( \frac{ΔV}{R} ) > 0.7 ( A ) \qquad [ Equation 7 ]$$

In Equation 7, ΔV may denote a voltage difference. In Equation 7, R may denote the resistance of a resistor. In Equation 7, 0.7(A) may denote 0.7 amperes.

If the voltage difference exceeds the third reference value (Yes in S849), in S851, the battery control method according to various exemplary embodiments of the present disclosure may include an operation of maintaining the states of relays included in a battery pack with a great voltage difference as ON states.

For example, the battery control method may include an operation of setting states of relays included in a battery pack with a great voltage difference as ON states.

In S853, the battery control method according to various exemplary embodiments of the present disclosure may include an operation of changing the state of an anode relay included in a battery pack with a small voltage difference to an ON state.

For example, the battery control method may include an operation of setting the states of the anode relays included in the battery pack with a small voltage difference as the ON states.

In S855, the battery control method according to various exemplary embodiments of the present disclosure may include an operation of changing the state of a PC relay included in a battery pack with a small voltage difference to the OFF state.

For example, the battery control method may include an operation of setting the state of the PC relay included in the battery pack with a small voltage difference as the OFF state.

If the voltage difference does not exceed the third reference value (No in S849), in S857, the battery control method according to various exemplary embodiments of the present disclosure may include an operation of changing the state of the anode relay included in the battery pack classified as the first group and the battery pack classified as the second group to the ON state.

For example, the battery control method may include an operation of setting the state of the anode relay included in the battery pack classified as the first group and the battery pack classified as the second group as the ON state.

In S859, the battery control method according to various exemplary embodiments of the present disclosure may include an operation of changing the state of the PC relay included in the battery pack classified as the first group and the battery pack classified as the second group to the OFF state.

For example, the battery control method may include an operation of setting the state of the PC relay included in the battery pack classified as the first group and the battery pack classified as the second group as the OFF state.

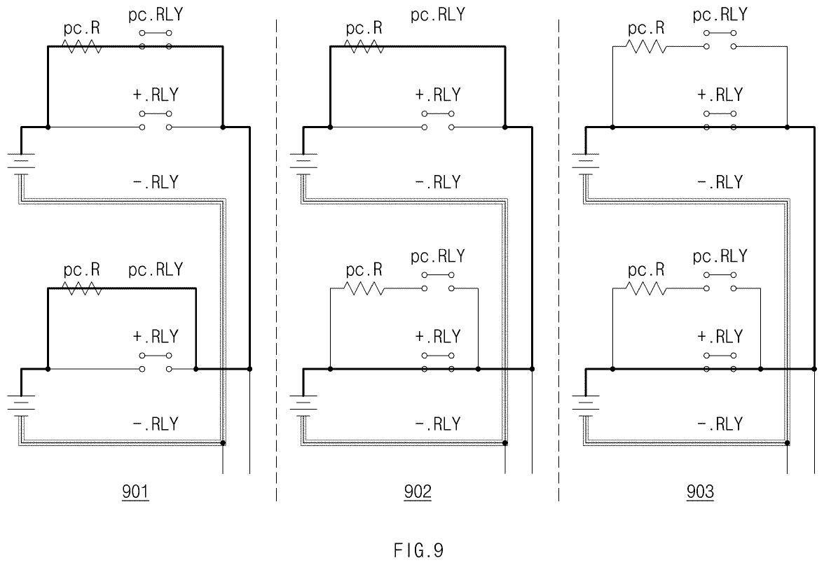

FIG. 9 shows an example in which each of battery pack is charged and discharged by relays controlled through a battery control apparatus, according to an exemplary embodiment of the present disclosure.

Referring to FIG. 9, a battery control apparatus according to various exemplary embodiments of the present disclosure may cause charging and/or discharging of battery packs by controlling relays included in the battery packs.

Referring to a first example 901 in FIG. 9, the battery control apparatus according to various exemplary embodiments of the present disclosure may set states of a PC relay and a cathode relay as ON states and may set a state of an anode relay as an OFF state among relays included in a plurality of battery packs.

If the relays are set as in the first example 901, the magnitude of the current may be set to a first level, that is, the minimum magnitude.

Referring to a second example 902 in FIG. 9, the battery control apparatus according to various exemplary embodiments of the present disclosure may set a state of a cathode relay as an OFF state among relays included in the plurality of battery packs. The battery control apparatus may set the state of the PC relay included in one battery pack among the plurality of battery packs as the ON state, and may set the state of the anode relay included in another battery pack as the ON state.

If the relays are set as in the second example 902, the magnitude of the current may be set to a second level, that is, a magnitude greater than the minimum magnitude and smaller than the maximum magnitude.

Referring to a third example 903, the battery control apparatus according to various exemplary embodiments of the present disclosure may set states of the anode relays and cathode relays included in the plurality of battery packs as ON states and may set states of PC relays to OFF states.

If the relays are set as in the third example 903, the magnitude of the current may be set to a third level, that is, the maximum magnitude.

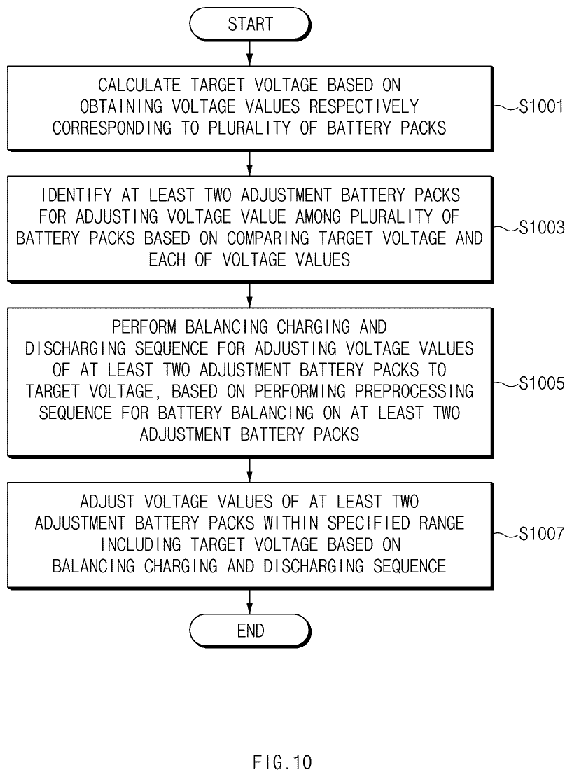

FIG. 10 shows an example of a flowchart associated with a battery control method, according to an exemplary embodiment of the present disclosure.

Hereinafter, it is assumed that the battery control apparatus 100 of FIG. 1 is configured to perform the process of FIG. 10. Furthermore, in a description of FIG. 10, it may be understood that an operation described as being performed by an apparatus is controlled by the processor 110 of the battery control apparatus 100.

At least one of operations of FIG. 10 may be performed by the battery control apparatus 100 of FIG. 1. At least one of operations of FIG. 10 may be performed by the processor 110 of FIG. 1. Each of the operations in FIG. 10 may be performed sequentially, but is not necessarily sequentially performed. For example, the order of operations may be changed, and at least two operations may be performed in parallel.

Referring to FIG. 10, in S1001, the battery control method according to various exemplary embodiments of the present disclosure may include an operation of determining a target voltage based on obtaining voltage values respectively corresponding to a plurality of battery packs.

In S1003, the battery control method according to various exemplary embodiments of the present disclosure may include an operation of identifying at least two adjustment battery packs for adjusting a voltage value among the plurality of battery packs based on comparing the target voltage and each of the voltage values.

In S1005, the battery control method according to various exemplary embodiments of the present disclosure may include an operation of performing a balancing charging and discharging sequence for adjusting voltage values of the at least two adjustment battery packs to the target voltage, based on performing the preprocessing sequence for battery balancing on the at least two adjustment battery packs.

In S1007, the battery control method according to various exemplary embodiments of the present disclosure may include an operation of adjusting the voltage values of the at least two adjustment battery packs within a predetermined range including the target voltage based on the balancing charging and discharging sequence.

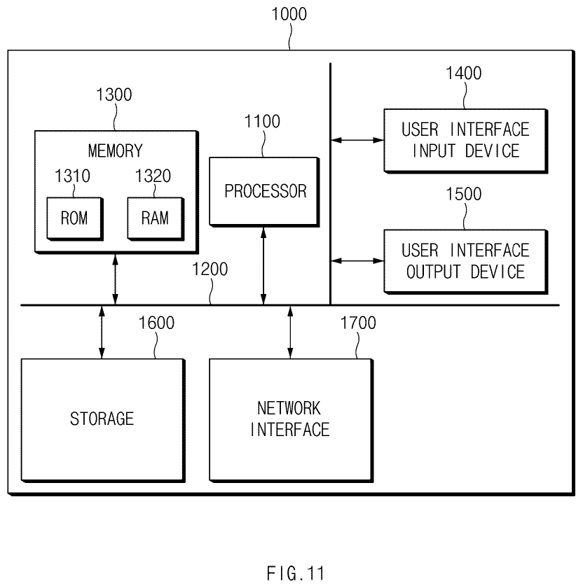

FIG. 11 shows a computing system associated with a battery control apparatus or battery control method, according to an exemplary embodiment of the present disclosure.

Referring to FIG. 11, a computing system 1000 may include at least one processor 1100, a memory 1300, a user interface input device 1400, a user interface output device 1500, storage 1600, and a network interface 1700, which are connected to each other via a bus 1200.

The processor 1100 may be a central processing unit (CPU) or a semiconductor device that processes instructions stored in the memory 1300 and/or the storage 1600. The memory 1300 and the storage 1600 may include various types of volatile or non-volatile storage media. For example, the memory 1300 may include a Read-Only Memory (ROM) 1310 and a Random Access Memory (RAM) 1320.

Accordingly, the processes of the method or algorithm described in relation to the exemplary embodiments of the present disclosure may be implemented directly by hardware executed by the processor 1100, a software module, or a combination thereof. The software module may reside in a storage medium (that is, the memory 1300 and/or the storage 1600), such as a RAM, a flash memory, a ROM, an EPROM, an EEPROM, a register, a hard disk, solid state drive (SSD), a detachable disk, or a CD-ROM. The exemplary storage medium is coupled to the processor 1100, and the processor 1100 may read information from the storage medium and may write information in the storage medium. In another method, the storage medium may be integrated with the processor 1100. The processor 1100 and the storage medium may reside in an application specific integrated circuit (ASIC). The ASIC may reside in a user terminal. In another method, the processor 1100 and the storage medium may reside in the user terminal as an individual component.

Hereinabove, although the present disclosure has been described with reference to exemplary embodiments and the accompanying drawings, the present disclosure is not limited thereto, but may be variously modified and altered by those skilled in the art to which the present disclosure pertains without departing from the spirit and scope of the present disclosure claimed in the following claims.

Therefore, the exemplary embodiments of the present disclosure are provided to explain the spirit and scope of the present disclosure, but not to limit them, so that the spirit and scope of the present disclosure is not limited by the embodiments. The scope of the present disclosure should be construed based on the accompanying claims, and all the technical ideas within the scope equivalent to the claims should be included in the scope of the present disclosure. The present technology may control relays included in battery packs.

Moreover, the present technology may adjust voltage values of battery packs to a target voltage by controlling the relays included in the battery packs.

Furthermore, the present technology may shorten a balancing time by performing balancing on the battery packs.

Besides, a variety of effects directly or indirectly understood through the present disclosure may be provided.

In various exemplary embodiments of the present disclosure, each operation described above may be performed by a control device, and the control device may be configured by a plurality of control devices, or an integrated single control device.

In various exemplary embodiments of the present disclosure, the memory and the processor may be provided as one chip, or provided as separate chips.

In various exemplary embodiments of the present disclosure, the scope of the present disclosure includes software or machine-executable commands (e.g., an operating system, an application, firmware, a program, etc.) for enabling operations according to the methods of various embodiments to be executed on an apparatus or a computer, a non-transitory computer-readable medium including such software or commands stored thereon and executable on the apparatus or the computer.

In various exemplary embodiments of the present disclosure, the control device may be implemented in a form of hardware or software, or may be implemented in a combination of hardware and software.

Furthermore, the terms such as “unit”, “module”, etc. included in the specification mean units for processing at least one function or operation, which may be implemented by hardware, software, or a combination thereof.

In the flowchart described with reference to the drawings, the order of operations may be changed, a plurality of operations may be merged, or any operation may be divided, and a predetermined operation may not be performed. Furthermore, the operations in the flowchart may be performed sequentially, but not necessarily performed sequentially. For example, the order of the operations may be changed, and at least two operations may be performed in parallel.

Hereinafter, the fact that pieces of hardware are coupled operably may include the fact that a direct and/or indirect connection between the pieces of hardware is established by wired and/or wirelessly.

In an exemplary embodiment of the present disclosure, the vehicle may be referred to as being based on a concept including various means of transportation. In some cases, the vehicle may be interpreted as being based on a concept including not only various means of land transportation, such as cars, motorcycles, trucks, and buses, that drive on roads but also various means of transportation such as airplanes, drones, ships, etc.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the present specification, unless stated otherwise, a singular expression includes a plural expression unless the context clearly indicates otherwise.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

According to an exemplary embodiment of the present disclosure, components may be combined with each other to be implemented as one, or some components may be omitted.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A battery control apparatus comprising:
a plurality of battery packs; and
a processor,
wherein the processor is configured to:
determine a target voltage based on obtaining voltage values respectively corresponding to the plurality of battery packs;
identify at least two adjustment battery packs for adjusting a voltage value among the plurality of battery packs based on comparing the target voltage and each of the voltage values;
perform a balancing charging and discharging sequence for adjusting voltage values of the at least two adjustment battery packs to the target voltage, based on performing a preprocessing sequence for battery balancing on the at least two adjustment battery packs; and
adjust the voltage values of the at least two adjustment battery packs within a first predetermined range including the target voltage based on the balancing charging and discharging sequence, wherein each of the battery packs includes at least two relays.

2. The battery control apparatus of claim 1, wherein the processor is further configured to:
set states of a plurality of relays included in the plurality of battery packs as OFF states;
determine an average value based on storing the voltage values respectively corresponding to the plurality of battery packs; and
set the average value to the target voltage for identifying the at least two adjustment battery packs.

3. The battery control apparatus of claim 1, wherein the processor is further configured to:
based on the comparing of the target voltage with each of the voltage values respectively corresponding to the plurality of battery packs:
classify a battery pack with a voltage value within a second predetermined range including the target voltage among the plurality of battery packs as a first group;
classify a battery pack with a voltage value, which exceeds a first value from the target voltage, from among the plurality of battery packs as a second group;
classify a battery pack with a voltage value, which is smaller than a second value from the target voltage, from among the plurality of battery packs as a third group; and
identify a battery pack included in at least one of the second group, or the third group, or any combination thereof as the at least two adjustment battery packs.

4. The battery control apparatus of claim 3, wherein the processor is further configured to:
obtain difference values between the target voltage and each of the voltage values based on the comparing of the target voltage with each of the voltage values respectively corresponding to the plurality of battery packs;
store the difference values based on sorting the difference values in a predetermined sorting method; and
perform the preprocessing sequence based on an order of the difference values.

5. The battery control apparatus of claim 1, wherein the processor is further configured to:
determine whether power of the at least two adjustment battery packs generated by a maximum current exceeds a rated power of a resistor, based on identifying the maximum current configured for being generated by the at least two adjustment battery packs; and
perform the preprocessing sequence based on the power of the at least two adjustment battery packs being smaller than or equal to the rated power.

6. The battery control apparatus of claim 1, wherein the preprocessing sequence is configured to:
set states of all relays as ON states by sequentially controlling the relays included in the at least two adjustment battery packs; and
set a state of at least part of the relays as an OFF state based on maintaining states of all the relays as the ON states during a predetermined time period.

7. The battery control apparatus of claim 1, wherein the processor is further configured to:
determine whether differences in voltage values between one battery pack included in the at least two adjustment battery packs and another battery packs other than the one of the at least two adjustment battery packs exceed a first reference value;
determine whether at least one of the differences is maintained at the first reference value during a period exceeding a predetermined duration, based on at least one of the differences exceeding the first reference value; and
set states of relays included in the at least two adjustment battery packs as OFF states based on the at least one of the differences being maintained at the first reference value during the period exceeding the predetermined duration.

8. The battery control apparatus of claim 7, wherein the processor is further configured to:
determine whether at least one of the differences exceeds a second reference value smaller than the first reference value, based on at least one of the differences being smaller than or equal to the first reference value; and
maintain the states of the relays included in the at least two adjustment battery packs as current states based on the at least one of the differences exceeding the second reference value.

9. The battery control apparatus of claim 8, wherein the processor is further configured to:
determine whether at least one of the differences exceeds a third reference value smaller than the second reference value, based on at least one of the differences being smaller than or equal to the second reference value;
based on the at least one of the differences exceeding the third reference value:
maintain states of relays included in an adjustment battery pack with a greatest voltage value among the at least two adjustment battery packs as current states;
set a state of an anode relay among relays included in an adjustment battery pack with a smallest voltage value among the at least two adjustment battery packs as an ON state; and
set a state of a pre-charger (PC) relay among the relays included in the adjustment battery pack with the smallest voltage value among the at least two adjustment battery packs as an OFF state.

10. The battery control apparatus of claim 9, wherein the processor is further configured to:
based on at least one of the differences being smaller than or equal to the third reference value:
set a state of an anode relay among relays included in the at least two adjustment battery packs to an ON state; and
set states of PC relays among the relays included in the at least two adjustment battery packs as OFF states.

11. A battery control method, the method comprising:
determining, by a processor, a target voltage based on obtaining voltage values respectively corresponding to a plurality of battery packs;
identifying, by the processor, at least two adjustment battery packs for adjusting a voltage value among the plurality of battery packs based on comparing the target voltage and each of the voltage values;
performing, by the processor, a balancing charging and discharging sequence for adjusting voltage values of the at least two adjustment battery packs to the target voltage, based on performing a preprocessing sequence for battery balancing on the at least two adjustment battery packs; and
adjusting, by the processor, the voltage values of the at least two adjustment battery packs within a first predetermined range including the target voltage based on the balancing charging and discharging sequence,
wherein each of the battery packs includes at least two relays.

12. The method of claim 11, further including:
setting, by the processor, states of a plurality of relays included in the plurality of battery packs as OFF states;
determining, by the processor, an average value based on storing the voltage values respectively corresponding to the plurality of battery packs; and
setting, by the processor, the average value to the target voltage for identifying the at least two adjustment battery packs.

13. The method of claim 11, further including:
based on the comparing of the target voltage with each of the voltage values respectively corresponding to the plurality of battery packs:
classifying, by the processor, a battery pack with a voltage value within a second predetermined range including the target voltage among the plurality of battery packs as a first group;
classifying, by the processor, a battery pack with a voltage value, which exceeds a first value from the target voltage, from among the plurality of battery packs as a second group;
classifying, by the processor, a battery pack with a voltage value, which is smaller than a second value from the target voltage, from among the plurality of battery packs as a third group; and
identifying, by the processor, a battery pack included in at least one of the second group, or the third group, or any combination thereof as the at least two adjustment battery packs.

14. The method of claim 13, further including:
obtaining, by the processor, difference values between the target voltage and each of the voltage values based on the comparing of the target voltage with each of the voltage values respectively corresponding to the plurality of battery packs;
storing, by the processor, the difference values based on sorting the difference values in a predetermined sorting method; and
performing, by the processor, the preprocessing sequence based on an order of the difference values.

15. The method of claim 11, further including:
determining, by the processor, whether power of the at least two adjustment battery packs generated by a maximum current exceeds a rated power of a resistor, based on identifying the maximum current configured for being generated by the at least two adjustment battery packs; and
performing, by the processor, the preprocessing sequence based on the power of the at least two adjustment battery packs being smaller than or equal to the rated power.

16. The method of claim 11, wherein the preprocessing sequence is configured to:
set states of all relays as ON states by sequentially controlling the relays included in the at least two adjustment battery packs; and
set a state of at least part of the relays as an OFF state based on maintaining states of all the relays as the ON states during a predetermined time period.

17. The method of claim 11, further including:
determining, by the processor, whether differences in voltage values between one battery pack included in the at least two adjustment battery packs and another battery packs other than the one of the at least two adjustment battery packs exceed a first reference value;
determining, by the processor, whether at least one of the differences is maintained at the first reference value during a period exceeding a predetermined duration, based on at least one of the differences exceeding the first reference value; and
setting, by the processor, states of relays included in the at least two adjustment battery packs as OFF states based on the at least one of the differences being maintained at the first reference value during the period exceeding the predetermined duration.

18. The method of claim 17, further including:
determining, by the processor, whether at least one of the differences exceeds a second reference value smaller than the first reference value, based on at least one of the differences being smaller than or equal to the first reference value; and
maintaining, by the processor, the states of the relays included in the at least two adjustment battery packs as current states based on the at least one of the differences exceeding the second reference value.

19. The method of claim 18, further including:
determining, by the processor, whether at least one of the differences exceeds a third reference value smaller than the second reference value, based on at least one of the differences being smaller than or equal to the second reference value;
based on the at least one of the differences exceeding the third reference value:
maintaining, by the processor, states of relays included in an adjustment battery pack with a greatest voltage value among the at least two adjustment battery packs as current states;
setting, by the processor, a state of an anode relay among relays included in an adjustment battery pack with a smallest voltage value among the at least two adjustment battery packs as an ON state; and
setting, by the processor, a state of a PC relay among the relays included in the adjustment battery pack with the smallest voltage value among the at least two adjustment battery packs as an OFF state.

20. The method of claim 19, further including:
based on at least one of the differences being smaller than or equal to the third reference value:
setting, by the processor, a state of an anode relay among relays included in the at least two adjustment battery packs to an ON state; and
setting, by the processor, states of PC relays among the relays included in the at least two adjustment battery packs as OFF states.
